(19) United States
(12) Patent Application Publication
(10) Pub. No.: US 2022/0246404 A1
(43) Pub. Date: Aug. 4, 2022

(54) SEALANT COATING FOR PLASMA PROCESSING CHAMBER COMPONENTS

(71) Applicant: Lam Research Corporation, Fremont, CA (US)

(72) Inventors: Benjamin Philip HEINE, Livermore, CA (US); Darrell EHRLICH, San Jose, CA (US); Robin KOSHY, Fremont, CA (US); Slobodan MITROVIC, Union City, CA (US); John DAUGHERTY, Fremont, CA (US)

(21) Appl. No.: 17/617,271

(22) PCT Filed: Jun. 10, 2020
(86) PCT No.: PCT/US2020/036995

§ 371 Date: Dec. 7, 2021

Related U.S. Application Data
(60) Provisional application No. 62/860,540, filed on Jun. 12, 2019.

(51) Int. Cl. H01J 37/32; H01L 21/683; C23C 14/12; C23C 14/58

(52) U.S. Cl. CPC H01J 37/32477; H01J 37/32715; H01J 2237/2007; C23C 14/12; C23C 14/5826; H01L 21/6833

(57) ABSTRACT

A component for use in a plasma processing chamber is provided. A metal containing component body is provided. A sealant coating is over a surface of the metal containing component body, wherein the sealant coating comprises at least one of a silicone sealant, an organic sealant, or epoxy sealant, wherein the sealant coating is not covered and directly exposed to plasma in the plasma processing chamber.

### CROSS-REFERENCE TO RELATED APPLICATION

This application claims the benefit of priority of U.S. Application No. 62/860,540, filed Jun. 12, 2019, which is incorporated herein by reference for all purposes.

### BACKGROUND

The present disclosure relates to the manufacturing of semiconductor devices. More specifically, the disclosure relates to plasma chamber components used in manufacturing semiconductor devices.

During semiconductor wafer processing, plasma processing chambers are used to process semiconductor devices. Components of plasma processing chambers are subjected to plasmas, which may degrade the component.

### SUMMARY

To achieve the foregoing and in accordance with the purpose of the present disclosure, a component for use in a plasma processing chamber is provided. A metal containing component body is provided. A sealant coating is over a surface of the metal containing component body, wherein the sealant coating comprises at least one of a silicone sealant, an organic sealant, or epoxy sealant, wherein the sealant coating is not covered and directly exposed to plasma in the plasma processing chamber.

In another manifestation, a method for forming a component of a plasma processing chamber is provided. A metal containing component body is provided. A sealant is applied over a surface of the metal containing component body.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-C are schematic views of part of a component processed according to an embodiment.

FIG. 3 is a schematic view of an plasma reactor that may be used in an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Materials that provide resistance to arcing are typically a metal oxide. Metal oxide is typically brittle, subject to cracking, and has relatively low coefficients of thermal expansion (CTE). Any crack induced through cycling across a wide range of temperatures will lead to electrical breakdown, causing the part to fail.

Current protective coatings on electrostatic chuck (ESC) baseplates include anodization, ceramic spray coat, or a spray coat on top of anodization. An aluminum nitride coating grown directly on the surface of aluminum baseplates is used in some products. Data show that anodization breaks down at approximately 2 kilovolts (kV) on a 0.002 inch thick coating when on a flat surface of aluminum, and at 600 volts (V) on corner radii. Spray coating, if applied normal to the surface, will withstand up to 10 kV on flat surfaces, but only about 4-5 kV on corner radii. Existing technology reaches its limits at these values since attempts to further improve the breakdown by making thicker coatings lead to cracking in response to thermal cycling, due to a mismatch between the CTE of the substrate and the CTE of coating materials.

The metal parts of an ESC can be subjected to large voltages as compared to the chamber body. Hence, it would be desirable to protect the metal parts of ESCs from chemical degradation and electrical discharge.

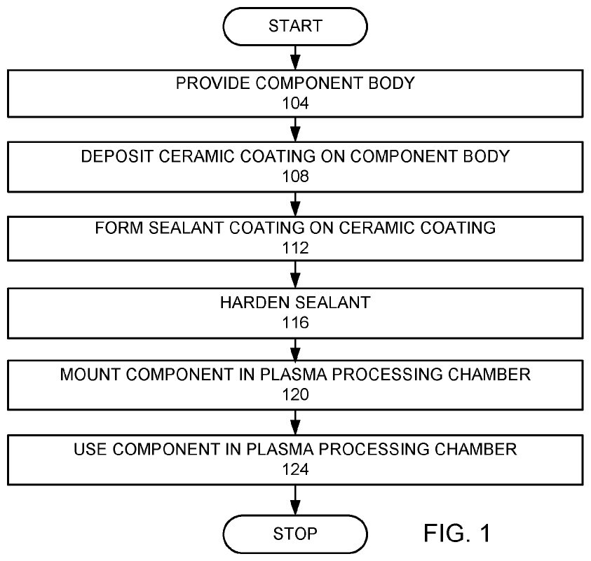

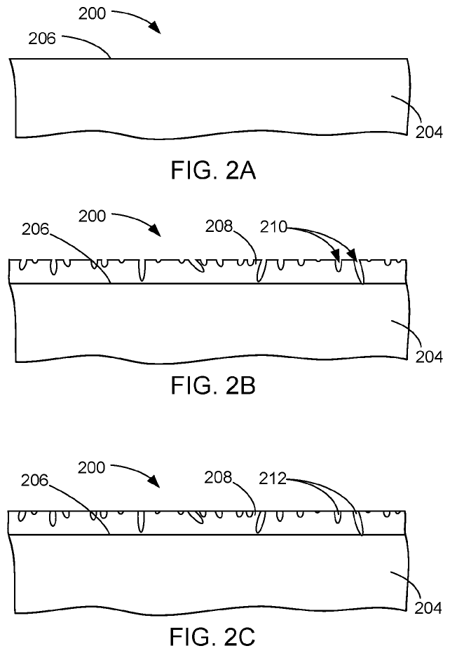

To facilitate understanding, FIG. 1 is a high level flow chart of a process used in an embodiment. A metal containing component body is provided (step 104). FIG. 2A is a schematic cross-sectional view of part of a metal containing component body 204 of a component 200. In this example, the component 200 is an electrostatic chuck (ESC). In this embodiment, the metal containing component body 204 is aluminum. The component body 204 has a surface 206. In this embodiment, the surface 206 is a plasma facing surface, or a surface exposed to radicals formed by a plasma, or a surface exposed to electrostatic charges during plasma processing.

A ceramic coating is deposited on the surface 206 of the metal containing component body 204 (step 108). FIG. 2B is a schematic cross-sectional view of the metal containing component body 204 after a ceramic coating 208 has been deposited on the surface 206 of the metal containing component body 204. In this embodiment, the ceramic coating 208 is alumina deposited by plasma spraying. In this embodiment, the plasma spraying causes the ceramic coating 208 to have pores 210.

Plasma spraying is a type of thermal spraying in which a torch is formed by applying an electrical potential between two electrodes, leading to ionization of an accelerated gas (a plasma). Torches of this type can readily reach temperatures of thousands of degrees Celsius, liquefying high melting point materials such as ceramics. Particles of the desired material are injected into the jet, melted, and then accelerated towards the substrate so that the molten or plasticized material coats the surface of the component and cool, forming a solid, conformal coating. Preferably, plasma spraying is used to deposit the ceramic coating 208. These processes are distinct from vapor deposition processes, which use vaporized material instead of molten material. In this embodiment, the thickness of the ceramic coating 208 is between 30 μm to 750 μm. In other embodiments, the ceramic coating 208 has a thickness of between 300 μm to 600 μm. In other embodiments, the ceramic coating 208 is a plasma electrolytic oxidation ceramic coating that has a thickness of between 30 μm to 200 μm. An example of a recipe for plasma spraying the ceramic coating 208 is as follows. A carrier gas is pushed through an arc cavity and out through a nozzle. In the cavity, a cathode and anode comprise parts of the arc cavity. The cathode and anode are maintained at a large DC bias voltage, until the carrier gas begins to ionize, forming the plasma. The hot, ionized gas is then pushed out through the nozzle forming the torch. Into the chamber near the nozzle is injected fluidized ceramic particles, tens of micrometers in size. These particles are heated by the hot, ionized gas in the plasma torch such that they exceed the melting temperature of the ceramic. The jet of plasma and melted ceramic is then aimed at a substrate. The particles impact the substrate, flattening and cooling to form a ceramic coating.

A sealant coating is formed on the ceramic coating 208 (step 112). In this example, the sealant is Loctite® PC 7319™ also known as Loctite® Nordbak® Chemical Resistant Coating™ manufactured by Henkel Corporation of Westlake Ohio. Loctite PC 7319 is an epoxy. It has been found that Loctite PC 7319 provides a breakdown voltage of greater than 2000 volts. Generally, the sealant is an organic sealant comprising at least one of a fluorinated polymer, perfluorinated polymer, silicone, epoxy sealant, or Parylene. The sealant may be applied by brush painting, spray painting, or dipping. In this embodiment, the sealant is applied by impregnation. The sealant is poured, soaked, or rubbed on the ceramic coating 208 to allow the sealant to soak into pores 210 of the ceramic coating 208. The sealant is then hardened. (step 116). The hardening of the sealant may be accomplished by drying, heating, or polymerizing the sealant to form the sealant coating.

FIG. 2C is a schematic cross-sectional view of the metal containing component body 204 after the sealant coating 212 is formed on the ceramic coating 208 over a surface of the metal containing component body 204. In this embodiment, the sealant fills the pores but does not form a continuous surface over the ceramic coating 208. In some embodiments, a top surface layer with a thickness of less than 50 microns is formed.

The component is mounted in a plasma processing chamber (step 120). The plasma processing chamber is used to process a substrate (step 124), where a plasma is created within the chamber to process the substrate, such as etching the substrate, and the unprotected sealant coating 212 is exposed to the plasma.

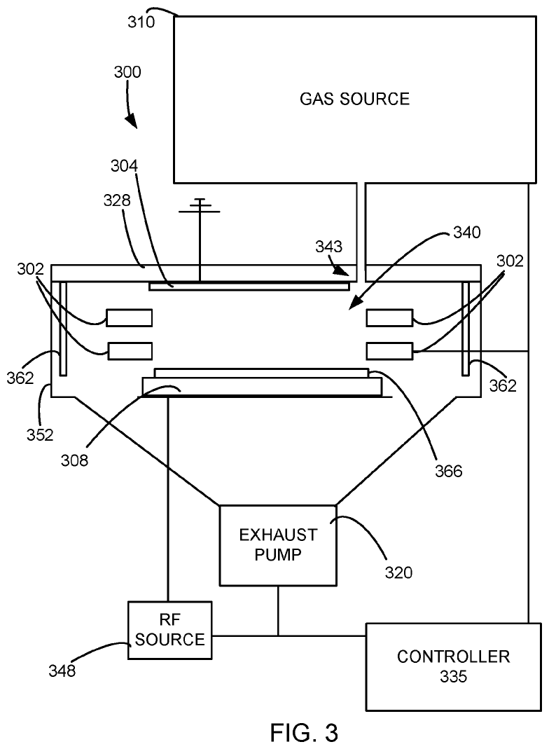

FIG. 3 is a schematic view of a plasma processing chamber 300 in which the component has been mounted. The plasma processing chamber 300 comprises confinement rings 302, an upper electrode 304, a lower electrode 308 in the form of an electrostatic chuck (ESC), a gas source 310, a liner 362, and an exhaust pump 320. In this example, the component is the ESC. Within plasma processing chamber 300, a wafer 366 is positioned upon the lower electrode 308. The lower electrode 308 incorporates a suitable substrate chucking mechanism (e.g., electrostatic, mechanical clamping, or the like) for holding the wafer 366. The reactor top 328 incorporates the upper electrode 304 disposed immediately opposite the lower electrode 308. The upper electrode 304, lower electrode 308, and confinement rings 302 define the confined plasma volume 340.

Gas is supplied to the confined plasma volume 340 through a gas inlet 343 by the gas source 310 and is exhausted from the confined plasma volume 340 through the confinement rings 302 and an exhaust port by the exhaust pump 320. Besides helping to exhaust the gas, the exhaust pump 320 helps to regulate pressure. A radio frequency (RF) source 348 is electrically connected to the lower electrode 308.

Chamber walls 352 surround the liner 362, confinement rings 302, the upper electrode 304, and the lower electrode 308. The liner 362 helps prevent gas or plasma that passes through the confinement rings 302 from contacting the chamber walls 352. Different combinations of connecting RF power to the electrode are possible. In a preferred embodiment, the 27 MHz, 60 MHz, and 2 MHz power sources make up the RF source 348 connected to the lower electrode 308, and the upper electrode 304 is grounded. A controller 335 is controllably connected to the RF source 348, exhaust pump 320, and the gas source 310. The plasma processing chamber 300 may be a CCP (capacitively coupled plasma) reactor or an ICP (inductively coupled plasma) reactor, or may use other sources like surface wave, microwave, or electron cyclotron resonance (ECR) may be used.

The resulting coating is resistant to chemical degradation and arcing. As a result, plasma processing chambers with such components will have fewer defects, while decreasing failure rates of such systems and increasing the time between the replacements of various parts.

In other embodiments, the sealant may be an organic coating comprising at least one of a fluorinated polymer, perfluorinated polymer, silicone, epoxy, or Parylene. In an embodiment, the sealant is Xylan® 1620 manufactured by Micro Surface Corporation of Morris, Ill. Xylan 1620 provides a fluoropolymer coating with a coefficient of friction as low as 0.02. In another embodiment, the sealant is a PCT S-Sealer previously manufactured by Protective Coating Technology of Haifa Bay Israel. PCT S-Sealer is an organo-ceramic self-planarized sealer. PCT S-Sealer has a coefficient of friction of 0.12. It has been found that PCT S-Sealer provides a breakdown voltage of greater than 5000 volts. In another embodiment, the sealant is dichtol WF 49 manufactured by Diamant of Germany. It has been found that dichtol WF 49 provides a breakdown voltage of greater than 2000 volts. In another embodiment, the sealant is Parylene. Parylene is formed from a poly(p-xylylene) polymer. The Parylene is deposited using a thermal process, where the gas is decomposed and then condensed on the ceramic coating 208. In various embodiments, the sealant may be used in a temperature range between about −60° C. to 300° C.

In various embodiments, the component may be other parts of a plasma processing chamber, such as confinement rings, edge rings, ground rings, chamber liners, door liners, or other components. The plasma processing chamber may be a dielectric processing chamber or conductor processing chamber. In some embodiments one or more, but not all surfaces are coated. The plasma processing chamber may be used for etching, deposition, or other substrate processes. Although in the above embodiment, a substrate support was provided by an ESC, in other embodiments the coating may be used on other substrate supports such as a pedestal or a substrate support without electrostatic chucking.

In other embodiments, the sealant coating 212 is deposited directly on the metal containing component body 204 without a ceramic coating 208. In various embodiments, the metal containing component body 204 may be aluminum or an aluminium matrix with silicon carbide particles (AlSiC). The aluminum component body 204 includes aluminum based alloys such as Aluminum 6061. The metal containing component body 204 may further comprise fillers, such as fillers of boron carbide or boron nitride.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. A component for use in a plasma processing chamber, comprising:
a metal containing component body; and
a sealant coating over a surface of the metal containing component body, wherein the sealant coating comprises at least one of a silicone based sealant, an organic sealant, or epoxy sealant, wherein the sealant coating is not covered and directly exposed to plasma in the plasma processing chamber.

2. The component, as recited in claim 1, wherein the sealant coating is an organic coating of at least one of a fluorinated polymer, perfluorinated polymer, silicone, epoxy, or poly(p-xylylene) polymer.

3. The component, as recited in claim 1, wherein the sealant coating is at least one of Parylene, PCT S-Sealer, Loctite PC 7319, Xylan 2630, and dichtol WF 49.

4. The component, as recited in claim 1, wherein the metal containing component body forms substrate support.

5. The component, as recited in claim 1, further comprising a ceramic coating on a surface of the metal containing component body, wherein the sealant coating is impregnated into the ceramic coating.

6. The component, as recited in claim 5, wherein the sealant coating is an organic coating of at least one of a fluorinated polymer, perfluorinated polymer, or poly(p-xylylene) polymer.

7. The component, as recited in claim 5, wherein the sealant coating is at least one of Parylene, PCT S-Sealer, Loctite PC 7319, Xylan 2630, and dichtol WF 49.

8. The component, as recited in claim 5, wherein the metal containing component body forms a substrate support.

9. A method for forming a component of a plasma processing chamber, comprising:
providing a metal containing component body; and
applying a sealant over a surface of the metal containing component body.

10. The method, as recited in claim 9, wherein the sealant is at least one of Parylene, PCT S-Sealer, Loctite PC 7319, Xylan 2630, and dichtol WF 49.

11. The method, as recited in claim 9, wherein the sealant is Parylene, wherein the applying the Parylene comprises:
vaporizing the Parylene; and
condensing the Parylene on the metal containing component body.

12. The method, as recited in claim 9, wherein the sealant is an organic sealant of at least one of a fluorinated polymer, perfluorinated polymer, silicone, epoxy, or poly(p-xylylene) polymer.

13. The method, as recited in claim 9, further comprising:
placing the metal containing component body in a plasma processing chamber; and
plasma processing a substrate in the plasma processing chamber, wherein the sealant is exposed to a plasma during the plasma processing.

14. The method, as recited in claim 9, wherein the metal containing component body forms a substrate support.

15. The method, as recited in claim 9, further comprising a depositing a ceramic coating on a surface of the metal containing component body, wherein the sealant is impregnated into the ceramic coating.

16. The method, as recited in claim 15, wherein the sealant is at least one of a fluorinated polymer, perfluorinated polymer, or poly(p-xylylene) polymer.

17. The method, as recited in claim 15, wherein the sealant is at least one of Parylene, PCT S-Sealer, Loctite PC 7319, Xylan 2630, and dichtol WF 49.

18. The method, as recited in claim 15, wherein the metal containing component body forms a substrate support.

19. The method, as recited in claim 9, further comprising hardening the sealant.
